(19) United States
(12) Patent Application Publication
(10) Pub. No.: US 2022/0290843 A1
(43) Pub. Date: Sep. 15, 2022

(54) Lighting Systems Including Photo-Luminescent Material

(71) Applicant: Ecosense Lighting Inc., Los Angeles, CA (US)

(72) Inventors: Noam Meir, Herzliya (IL); Ariel Meir, North Miami Beach, FL (US)

(21) Appl. No.: 17/649,395

(22) Filed: Jan. 31, 2022

Related U.S. Application Data
(63) Continuation of application No. PCT/US2019/062593, filed on Nov. 21, 2019.
Application No. PCT/US2019/062593 is a continuation of application No. PCT/US2019/044715, filed on Aug. 1, 2019.
(60) Provisional application No. 62/713,437, filed on Aug. 1, 2018.

(51) Int. Cl. F21V 9/40; F21V 7/00; H01L 33/50

(52) U.S. Cl. CPC F21V 9/40; F21V 7/0066; H01L 33/502; F21Y 2115/10

(57) ABSTRACT

Lighting systems and, in particular, lighting systems that include one or more LEDs and photo-luminescent material.

### CROSS-REFERENCE TO RELATED APPLICATIONS

This application is a continuation of and claims priority to Patent Cooperation Treaty (PCT) International Patent Application Serial No. PCT/US2019/062593, filed Nov. 21, 2019, entitled Lighting Systems Including Photo-Luminescent Material, and is a continuation of and claims priority to Patent Cooperation Treaty (PCT) International Patent Application Serial No. PCT/US2019/044715, filed Aug. 1, 2019, entitled Lighting Systems Including Photo-Luminescent Material, which claims the benefit of and priority to U.S. Provisional Patent Application Ser. No. 62/713,437, filed Aug. 1, 2018, entitled Lighting Systems Including Photo-Luminescent Material, all of which are commonly-owned and all of which are hereby incorporated herein by reference as if fully set forth herein in their entirety.

### FIELD

This disclosure relates to lighting systems and, in particular, lighting systems that include one or more LEDs and photo-luminescent material.

### BACKGROUND

Light emitting diodes (LEDs) are typically formed from a semiconductor material that is doped to create a p-n junction. The LEDs typically emit light in a narrow spectrum (e.g., a spectrum that is smaller 200 nanometers in size) that is dependent upon the bandgap energy of the semiconductor material that forms the p-n junction. For example, an LED formed using one semiconductor material may emit light of a different color (and thereby in a different spectrum) than an LED formed using another semiconductor material.

White light has a broad spectrum (e.g., a spectrum that is larger than 200 nanometers in size), unlike the light typically emitted from a single LED. White light may be formed by mixing light with different colors (and thereby different spectrums) together. For example, white light may be formed by mixing red, green, and blue light or blue and yellow light. Inexpensive LEDs that create white light (a white LED) typically use an LED configured to emit blue light (a blue LED) that is coated with a yellow phosphor. The yellow phosphor coating converts a portion of the blue light from the LED into yellow light. The mixture of the blue and yellow light forms white light.

### SUMMARY

Lighting systems that include one or more LEDs and photo-luminescent material are described herein.

In one aspect, a lighting system is provided. The lighting system comprises a light emitting diode (LED) configured to emit light having a first wavelength. The LED including a phosphor material coating configured to convert a portion of the light emitted by the LED to light having a second wavelength. The system further comprising a waveguide material surrounding, in part, the LED. The system further comprising a photo-luminescent material arranged within and/or on the waveguide material. The photo-luminescent material is configured to convert light having the first wavelength to a different wavelength and light having the second wavelength to a different wavelength. The lighting system is configured to emit light at each wavelength from at least 450-750 nm, wherein the light emission at each wavelength is at least 30% of the peak light emission between 450-750 nm.

In some embodiments, the LED may be configured to emit blue light and the phosphor material coating is configured to convert a portion of the light emitted by the LED to yellow light. The LED may be mounted on a circuit board.

In some embodiments, the waveguide material encapsulates, in part, the LED so that an emission surface of the LED is in contact with the waveguide material. The waveguide material can encapsulate, in part, the circuit board. The waveguide material comprises a silicone material.

In some embodiments, a plurality of different types of photo-luminescent materials may be arranged within and/or on the waveguide material. For example, the plurality of different types of photo-luminescent materials can comprise quantum dot material, phosphor material and organic material and/or organic compounds.

In some embodiments, the lighting system may emit light at each wavelength from at least 400-800 nm, wherein the light emission at each wavelength is at least 30% of the peak light emission between 400-800 nm.

In some embodiments, the waveguide material can be contained, in part, within a reflector component. For example, the reflector component is cup-shaped.

In one aspect, a lighting system is provided. The lighting system comprises a light emitting diode (LED) configured to emit light having a first wavelength. The LED includes a phosphor material coating configured to convert a portion of the light emitted by the LED to light having a second wavelength. The lighting system further comprises a waveguide material surrounding, in part, the LED. Photo-luminescent material is arranged within and/or on the waveguide material. The photo-luminescent material is configured to convert light having the first wavelength to a different wavelength and light having the second wavelength to a different wavelength. The lighting system further comprises a reflector component configured to contain the waveguide material and direct light out of the light emitting system.

In some embodiments, the reflector component is cup-shaped. The reflector component may comprise a silicone material.

In some embodiments, the LED is configured to emit blue light and the phosphor material coating is configured to convert a portion of the light emitted by the LED to yellow light. The LED may be mounted on a circuit board.

In some embodiments, the waveguide material encapsulates, in part, the LED so that an emission surface of the LED is in contact with the waveguide material. The waveguide material may encapsulate, in part, the circuit board. The waveguide material may comprise a silicone material.

In some embodiments, a plurality of different types of photo-luminescent materials are arranged within and/or on the waveguide material. The plurality of different types of photo-luminescent materials comprise quantum dot material, phosphor material and organic material and/or organic compounds.

In some embodiments, the lighting system emits light at each wavelength from at least 400-800 nm, wherein the light emission at each wavelength is at least 20% of the peak light emission between 400-800 nm.

Other aspects, embodiments and features will become apparent from the following non-limiting detailed description when considered in conjunction with the accompanying drawings, which are schematic and which are not intended to be drawn to scale. In the figures, each identical or nearly identical component that is illustrated in various figures typically is represented by a single numeral. For purposes of clarity, not every component is labeled in every figure, nor is every component of each embodiment shown where illustration is not necessary to allow those of ordinary skill in the art to understand the invention. In cases where the present specification and a document incorporated by reference include conflicting disclosure, the present specification shall control.

### BRIEF DESCRIPTION OF THE DRAWINGS

FIG. 1 shows a side view of a lighting system according to some embodiments described herein;

FIG. 2 shows an overhead view of the lighting system of FIG. 1A according to some embodiments of the technology described herein;

FIG. 3 shows a graph of the power intensity per nm across the spectrum of visible light for a lighting system as described in the Example.

### DETAILED DESCRIPTION

Lighting systems that include one or more LEDs and photo-luminescent material are described herein. The LED(s) may be coated with a phosphor material which converts a portion of the blue light emitted by the LED(s) to yellow light, while a portion of the emitted light remains unconverted (i.e., blue). The LEDs may be surrounded, in part, by a waveguide material (e.g., a silicone material) which can enhance light extraction from the LEDs. The system may include additional photo-luminescent material (e.g., of more than one type) incorporated within and/or on the waveguide material. The additional photo-luminescent material may convert the wavelength(s) of light emitted from the LEDs. The type(s) of additional photo-luminescent material may be selected to produce light having the desired wavelength. For example, the additional photo-luminescent material may convert blue light (i.e., blue light unconverted by the phosphor material) from the LEDs to light of a different wavelength such as green light, in some embodiments; and/or, to cyan light and/or infrared light in some embodiments. Additional photo-luminescent material may also convert yellow light (i.e., yellow light that was converted by the phosphor material) from the LEDs to light of a different wavelength such as red light, deep red light and/or far red light. As described further below, by selecting suitable types of additional photo-luminescent materials, it may be possible, for example, to produce light that is emitted from the system across the full visible spectrum which mimics sun light. Such spectral illumination characteristics can make the lighting systems described herein particularly desirable in a number of applications including general lighting.

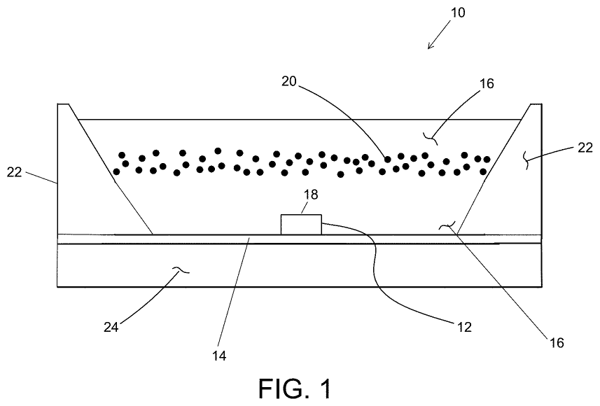

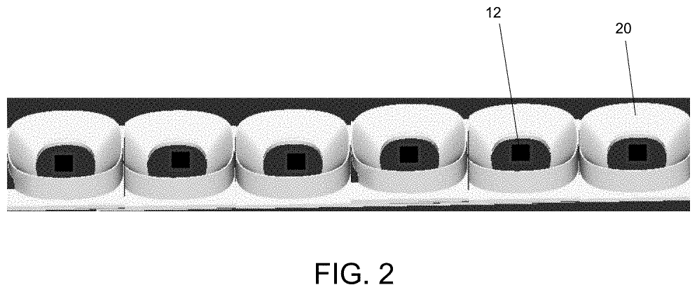

FIG. 1 shows a cross-sectional view of a portion of a lighting system 10. As shown, the system includes an LED 12 that is positioned on a substrate such as a circuit board 14. Though FIG. 1 shows only a single LED, it should be understood that in systems that include a series of LEDs, the structure shown in the cross-section of FIG. 1 may be similar or the same surrounding each LED in the series (e.g., along a strip as shown in FIG. 2). FIG. 2 shows an example of a strip lighting system according to some embodiments, as described further below.

The LED is surrounded by a waveguide material 16 such as a silicone material. As shown, the LED is encapsulated by the waveguide material such that the waveguide material is in contact with an emission surface 18 of the LED. In some cases, an air gap may be present between the emission surface and the waveguide material. Photo-luminescent materials 20 are distributed within and/or on the waveguide material. As described above and further below, different types and/or different concentrations of photo-luminescent materials may be selected to provide the desired light emission (e.g., across full visible spectrum) from the system.

In the embodiment shown in FIG. 1, the waveguide material is contained in a reflector 22 which may be in the shape of a cup that is configured to reflect light upwards out of the system. As shown, the circuit board may be mounted on an optional base 24.

It should be understood that the lighting systems described herein may include a number of variations to the system shown in FIG. 1. For example, the lighting systems may include additional components such as an optical component (e.g., a lens). In some cases, the lighting systems may include one or more films that are arranged, for example, over the reflector cup. The film(s) may comprise a photo-luminescent material.

FIG. 2 shows a lighting system 10 in the form of a strip. The strip includes a series of LEDs 12 arranged in respective reflectors 22 that contain waveguide material in which the photo-luminescent materials are distributed. The strip may include a series of portions (e.g., identical portions) that are joined together using connectors. The connector(s) may electrically couple each LED to an external device such as another lighting device or a power adapter. The LED may receive power from the external device via the connector and emit light.

Suitable strip lighting systems may have a construction similar to those described in U.S. Pat. Nos. 9,976,710 and 10,132,476 both of which are incorporated herein by reference in its entirety. It should be understood that the lighting system may have a variety of different configurations that are not shown including non-strip configurations.

In general, LED 12 may have any suitable design. For example, the LED may be a semiconductor device that is configured to emit light. In some embodiments, it may be preferable to use an LED that includes a phosphor material coating. For example, the LED may emit blue light (or UV light, or violet light) and a portion of the blue light is converted to a different wavelength (e.g., yellow) by the phosphor coating. In some embodiments, a portion of the light emitted from the LED is unconverted by the phosphor coating and remains blue.

It should be understood that, in some embodiments, other types of LEDs may be used in the lighting systems described herein. Such LEDs may or may not include phosphor coatings. Certain systems may include more than one type of LED and/or phosphor coating. For example, certain systems may include LEDs that emit different types of light (e.g., UV, blue, red, green, etc.).

As shown, the LED is mounted on circuit board 14. In general, the circuit board may have any suitable design and configuration. The circuit board may be, for example, a flexible printed circuit board (PCB) (e.g., an FR4 PCB) to allow the lighting system to bend without breaking. Various electrical components as needed for the operation of the lighting system may also be mounted on the circuit board.

In some embodiments, the circuit board, or at least a portion thereof, is surrounded by (e.g., encapsulated) by waveguide material 16.

It should be understood that, in some embodiments, the LED may be mounted on a different type of substrate (e.g., not a circuit board) in the lighting systems described herein.

As described above, the system may (or may not) include base 24 on which the circuit board is mounted. In some embodiments, the base may be designed (e.g., by including features) to engage with the reflector.

In general, waveguide material 16 may comprise any suitable material. Light emitted by the LED is suitably transmitted through the waveguide material. In some embodiments, the waveguide material may comprise a polymeric material such as an elastomer. In certain embodiments, it may be preferable for the waveguide material to comprise a silicone material. In some embodiments, the waveguide material is formed primarily (e.g., greater than 50% by weight, greater than 70% by weight, greater than 90% by weight) or essentially entirely of silicone. In some embodiments, the waveguide material may consist essentially of a silicone material.

In some embodiments, additives (e.g., particles) may be added to the silicone material to impart desirable properties (e.g., reflectivity).

In some embodiments, the silicone material may be highly reflective. In some such embodiments, the silicone may have a white reflective color (e.g., white silicone). Suitable silicones include CI-2001 (Dow Corning) and MS-2002 (Dow Corning). In some embodiments, the reflective silicone may have a reflectance of at least 93% for light (e.g., in the visible region). In some cases, the reflective silicone may have a reflectance of at least 95% for light (e.g., in the visible region).

In some embodiments, the waveguide material may be a potting material.

As described above, the system may include additional photo-luminescent material (e.g., of more than one type) incorporated within and/or on the waveguide material. The additional photo-luminescent material may convert the wavelength(s) of light emitted from the LEDs. In some embodiments, photo-luminescent material may be in particle form. The particles may be distributed within the waveguide material so that the waveguide material encapsulates the photo-luminescent material particles. In some cases, the photo-luminescent material (e.g., particles) may be distributed within a region of the waveguide material. For example, one type of photo-luminescent material may be distributed within one region of the waveguide material and a different type of photo-luminescent material may be distributed within a different region of the waveguide material. In some cases, the photo-luminescent materials (e.g., particles) may be part of a layer that is incorporated into the waveguide material. Such layers may be encapsulated within the waveguide material. Different types of photo-luminescent materials may be incorporated into different layers.

In some embodiments, the photo-luminescent material (e.g., particles) are distributed on one of the waveguide surfaces through which light passes. In such embodiments, the photo-luminescent material (e.g., particles) may be incorporated into a layer which is arranged on one of the waveguide surfaces.

In general, any suitable type of additional photo-luminescent material may be incorporated within and/or on the waveguide material. Suitable types include quantum dot materials (e.g., cadmium-free quantum dots), phosphor materials (e.g., neodymium-doped yttrium aluminum garnet (Nd:YAG)), silicates and quantum dots (e.g., cadmium-free quantum dots). The photo-luminescent material may be an organic material and/or comprise organic compounds. Additionally (or alternatively), the photo-luminescent material may be an inorganic material and/or comprise inorganic compounds.

In embodiments which utilize quantum dots, generally any suitable quantum dot that leads to the desired wavelength conversion may be used. In some embodiments, the quantum dot materials may convert blue light (e.g., emitted by the LED and not converted by the phosphor coating) to cyan light; and, in some embodiments, the quantum dot materials may convert blue light to red light (626-655 nm) and/or deep red light (656-699 nm) and/or far red light (700-800 nm) and/or infrared light (801-1050 nm). It should be understood that the lighting systems described herein may include quantum dot materials that convert light to any desired wavelength (e.g., from UV-IR spectrum).

In some cases, the quantum dots may be perovskite quantum dots. For example, the quantum dots may be comprised of CsPb-based compounds such as CsPb(ClxBr1-x)3. Suitable quantum dots may be purchased from Quantum Solutions (www.quantum-solutions.com).

In embodiments which utilize phosphor materials as an additional photo-luminescent material, generally any suitable phosphor material that leads to the desired wavelength conversion may be used. In some embodiments, the phosphor material may be a different phosphor material than the phosphor material coating on the LED(s); though, in some embodiments, the phosphor material may be the same phosphor material as the phosphor material coating on the LED(s). In some cases, the phosphor material converts blue light to green light. It should be understood that the lighting systems described herein may include phosphor materials that convert light to any desired wavelength (e.g., from UV-IR spectrum).

In embodiments which utilize organic material and/or organic compounds as an additional photo-luminescent material, generally any suitable such materials that leads to the desired wavelength conversion may be used. In some embodiments, the organic material and/or organic compounds may be any of the color conversion materials described in U.S. Patent Publication No. 2017/0137627 and International Patent Application Publication WO2017/085707, both of which are incorporated herein by reference in their entireties. For example, the organic material may be a rhodamine-based compound. Suitable organic material and/or organic compounds that are commercially available may be known as MolecuLED material. In some cases, the organic material and/or organic compounds may convert yellow light to red light and/or deep red light. It should be understood that the lighting systems described herein may include organic material and/or organic compounds that convert light to any desired wavelength (e.g., from UV-IR spectrum).

As described above, the type(s) and/or concentration of additional photo-luminescent material may be selected to produce light having the desired wavelength(s). By selecting suitable types of additional photo-luminescent materials, it may be possible, for example, to produce light that is emitted from the lighting system across the full visible spectrum which mimics sun light. In such embodiments, the light may be emitted at each wavelength (or, in some cases, at least 95% of the wavelengths) within the visible spectrum (e.g., from 450-750 nm; or, from 400-800 nm) and, in some embodiments, at each wavelength (or, in some cases, at least 95% of the wavelengths) within the spectrum from UV-IR (e.g., from 350-900 nm). For example, the light emission (e.g., as measured by power intensity per nm) at each wavelength (or, in some cases, at least 95% of the wavelengths) within such spectrums (e.g., from 450-750 nm; from 400-800 nm; from 350-900 nm) may be at least 20% of the peak light emission within such spectrum; the light emission at each wavelength (or, in some cases, at least 95% of the wavelengths) within such spectrums (e.g., from 450-750 nm; from 400-800 nm; from 350-900 nm) may be at least 30% of the peak light emission within such spectrum; in some embodiments, the light emission at each wavelength (or, in some cases, at least 95% of the wavelengths) within such spectrums (e.g., from 450-750 nm; from 400-800 nm; from 350-900 nm) may be at least 50% of the peak light emission within such spectrum; and, in some embodiments, the light emission at each wavelength (or, in some cases, at least 95% of the wavelengths) within such spectrums (e.g., from 450-750 nm; from 400-800 nm; from 350-900 nm) may be at least 60% of the peak light emission within such spectrum. In other words, in such embodiments, the dip in light emission across such spectrums may be minimal. Thus, light may be emitted across the full visible spectrum which mimics sunlight.

It should be understood that, in some embodiments, the type(s) of additional photo-luminescent material may be selected to produce light that is not emitted across the full visible spectrum; but, rather is emitted across other wavelengths. The desired emission and, thus, type of photo-luminescent materials utilized will be dictated by the desired end use.

As described above, the lighting systems described herein may include reflector (also referred to herein as a reflector component) 22 which is configured to contain the waveguide material. In some embodiments, the reflector may be in the shape (e.g., a cup) that is configured to reflect light upwards out of the system. In some embodiments, the reflector may be mounted to the base.

The reflector may be made of any suitable material. For example, the reflector may be made of a highly reflective material. In some cases, the reflector may comprise a silicone material. In some embodiments, the reflector is formed primarily (e.g., greater than 50% by weight, greater than 70% by weight, greater than 90% by weight) or essentially entirely of silicone. In some embodiments, the reflector may consist essentially of a silicone material. In some embodiments, additives (e.g., particles) may be added to the silicone material of the CSM to impart desirable properties (e.g., reflectivity). For example, titanium dioxide (TiO2) may be added to the silicone material. In some embodiments between 3-10 weight percent titanium dioxide may be added.

In some embodiments, the silicone may be highly reflective. In some such embodiments, the silicone may have a white reflective color (e.g., white silicone). Suitable silicones include CI-2001 (Dow Corning) and MS-2002 (Dow Corning). In some embodiments, the reflective silicone may have a reflectance of at least 93% for light in the visible region. In some cases, the reflective silicone may have a reflectance of at least 95% for light in the visible region. In some embodiments, the silicone has a material reflectivity of at least 90% and, in some cases, at least 95%.

The following examples are included for illustrative purposes only and are not intended to be limiting.

### Example

A lighting system according to some embodiments described herein was modeled for performance. The system includes a phosphor-coated LED that was encapsulated in a silicone material in which different photo-luminescent materials are contained. The photo-luminescent materials were the following:

1) Organic (e.g., MolecuLED like #6 that converts yellow light to the red, deep red, far red regions)
2) Quantum dot material (e.g., QD-P-510 CsPb(Br_{0.75}, Cl_{0.25})₃ that converts blue light to the Cyan region
3) Quantum dot material (e.g., QD-LS-800-abs) that converts blue light to far red region, IR region
4) Phosphor material that converts blue light to the green region

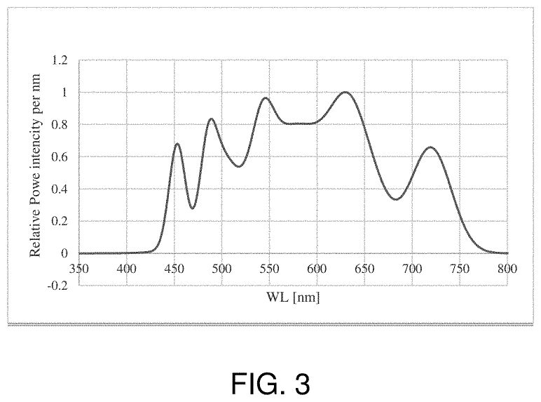

FIG. 3 shows a graph of the power intensity per nm across the spectrum of visible light. As shown, the light emitted from the lighting system across the full visible spectrum mimics sun light. The graph illustrates that light is emitted at each wavelength within the visible spectrum from at least 450-750 nm. Across this spectrum, the light emission (e.g., as measured by power intensity per nm) at each wavelength is at least 30% of the peak light emission (at about 630 nm) within such spectrum.

The Table below shows the details from which the graph shown in FIG. 3 is generated.

| | | Wave Length | | Pick | Band | | |
|---|---|---|---|---|---|---|---|
| | Bin | band [nm] | | WL | Width | FWHM | Amp |
| 1 | UV | 350 | 400 | 375 | 50 | 20 | 0 |
| 2 | Violet | 401 | 435 | 418 | 34 | 20 | 0 |
| 3 | Royal Blue | 436 | 470 | 453 | 34 | 20 | 0.8 |
| 4 | Blue | 471 | 500 | 485.5 | 29 | 20 | 0.6 |
| 5 | Cyan | 501 | 520 | 500 | 19 | 30 | 0.4 |
| 6 | Green | 521 | 565 | 543 | 44 | 25 | 0.4 |
| 7 | Yellow | 566 | 590 | 578 | 24 | 120 | 1 |
| 8 | Orange | 591 | 625 | 608 | 34 | 35 | 0 |
| 9 | Red | 626 | 655 | 630 | 29 | 40 | 0.4 |
| 10 | Deep Red | 656 | 699 | 650 | 43 | 50 | 0.4 |
| 11 | Far Red | 700 | 800 | 720 | 100 | 50 | 0.8 |
| 12 | IR | 801 | 1050 | 925.5 | 249 | 50 | 0 |

This example illustrates how different photo-luminescent materials may be incorporated into a lighting system to provide a desired emission spectrum.

Various aspects of the present disclosure may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately,” “about,” and “substantially” may be used to mean within ±20% of a target value in some embodiments, within ±10% of a target value in some embodiments, within ±5% of a target value in some embodiments, and yet within ±2% of a target value in some embodiments. The terms “approximately,” “about,” and “substantially” may include the target value.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having described above several aspects of at least one embodiment, it is to be appreciated various alterations, modifications, and improvements will readily occur to those skilled in the art. Such alterations, modifications, and improvements are intended to be object of this disclosure. Accordingly, the foregoing description and drawings are by way of example only.

1. A lighting system, comprising:
a light emitting diode (LED) having a light emission surface to emit light in an emission direction, the light having a first wavelength, the LED including a phosphor material coating over the light emission surface to convert a portion of the light emitted by the LED to light having a second wavelength;
a waveguide material surrounding, in part, the light emission surface of the LED; and
a photo-luminescent material arranged within or on the waveguide material, wherein the photo-luminescent material is in an alignment with the emission direction to convert light having the first wavelength to a different wavelength and to convert light having the second wavelength to another different wavelength,
wherein the alignment causes the lighting system to emit light in the emission direction at each wavelength throughout a range of at least between about 450 nm and about 750 nm to mimic sunlight, and wherein the alignment causes a mixing of light emission wavelengths at each wavelength having intensities of at least about 20% of the peak light emission intensities, throughout the range of between about 450 nm and about 750 nm.

2. The lighting system of claim 1, wherein the LED is configured to emit the light having the first wavelength as being blue light and wherein the phosphor material coating is configured to convert a portion of the light emitted by the LED to light having the second wavelength as being yellow light.

3. (canceled)

4. The lighting system of claim 1 wherein the waveguide material encapsulates, in part, the LED so that the light emission surface of the LED is in contact with the waveguide material.

5. (canceled)

6. The lighting system of claim 1 wherein the waveguide material includes a silicone material.

7. The lighting system of claim 1, wherein the photo-luminescent material includes a plurality of different types of photo-luminescent materials arranged within or on the waveguide material.

8. The lighting system of claim 7, wherein the plurality of different types of photo-luminescent materials includes a quantum dot material, a phosphor material, an organic compound, or an inorganic compound.

9. The lighting system of claim 1, wherein the alignment causes the lighting system to emit light in the emission direction at each wavelength throughout a range of at least between about 400 nm and about 800 nm, and wherein the alignment causes the mixing of the light emission wavelengths at each wavelength to have intensities of at least about 20% of the peak light emission intensities, throughout the range of between about 400 nm and about 800 nm.

10. The lighting system of claim 1, wherein the waveguide material is contained, in part, within a reflector component.

11. The lighting system of claim 10, wherein the reflector component is cup-shaped.

12. A lighting system, comprising:
a light emitting diode (LED) having a light emission surface to emit light in an emission direction, the light having a first wavelength, the LED including a phosphor material coating over the light emission surface to convert a portion of the light emitted by the LED to light having a second wavelength;
a waveguide material surrounding, in part, the light emission surface of the LED;
a photo-luminescent material arranged within or on the waveguide material, wherein the photo-luminescent material is in an alignment with the emission direction to convert light having the first wavelength to a different wavelength and to convert light having the second wavelength to another different wavelength; and
a reflector component containing the waveguide material and directing the light out of the lighting system.

13. The lighting system of claim 12, wherein the reflector component is cup-shaped.

14. The lighting system of claim 12, wherein the reflector component includes a silicone material.

15. The lighting system of claim 12, wherein the LED is configured to emit the light having the first wavelength as being blue light and wherein the phosphor material coating is configured to convert a portion of the light emitted by the LED to light having the second wavelength as being yellow light.

16. The lighting system of claim 13, further including a film over the cup-shaped reflector component, the film including a photo-luminescent material.

17. The lighting system of claim 12, wherein the waveguide material encapsulates, in part, the LED so that the light emission surface of the LED is in contact with the waveguide material.

18. (canceled)

19. The lighting system of claim 12, wherein the waveguide material includes a silicone material.

20. The lighting system of claim 12, wherein the photo-luminescent material includes a plurality of different types of photo-luminescent materials arranged within or on the waveguide material.

21. The lighting system of claim 20, wherein the plurality of different types of photo-luminescent materials includes a quantum dot material, a phosphor material, an organic compound, or an inorganic compound.

22. The lighting system of claim 12, wherein the alignment causes the lighting system to emit light in the emission direction at each wavelength throughout a range of at least between about 400 nm and about 800 nm to mimic sunlight, and wherein the alignment causes the mixing of the light emission wavelengths at each wavelength to have intensities of at least about 20% of the peak light emission intensities, throughout the range of between about 400 nm and about 800 nm.

23. The lighting system of claim 11, further including a film over the cup-shaped reflector component, the film including a photo-luminescent material.
